(19) United States
(12) Patent Application Publication
(10) Pub. No.: US 2011/0002161 A1
(43) Pub. Date: Jan. 6, 2011

(54) PHASE CHANGE MEMORY CELL WITH SELECTING ELEMENT

(75) Inventors: Insik Jin, Eagan, MN (US); Nurul Amin, Woodbury, MN (US); Wei Tian, Bloomington, MN (US); Young Pil Kim, Eden Prairie, MN (US); Venugopalan Vaithyanathan, Bloomington, MN (US); Ming Sun, Eden Prairie, MN (US); Chulmin Jung, Eden Prairie, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/497,995

(22) Filed: Jul. 6, 2009

(51) Int. Cl. G11C 11/00

(52) U.S. Cl. 365/163; 365/148

(57) ABSTRACT

A memory cell comprising a phase-change memory cell stacked in series with a resistive switch. The resistive switch has a material switchable between a high resistance state and a low resistance state by the application of a voltage. A plurality of memory cells are used to form a memory array.

### BACKGROUND

Phase change (PC) memory is an emerging technology for high-speed, low power and high density memory devices. PC memory cells include a material that changes phases, between crystalline and amorphous, at temperatures of about 200° C. or greater. At ambient temperature (e.g., below 150° C.) both phases are stable. When in the crystalline phase, the PC memory cell has a low resistance, whereas when in the amorphous phase, the PC memory cell has a high resistance.

To achieve high density PC memory, 3-dimensional stacking of PC cells in a memory array is used. In such a memory array, a selective element or switch is required, in addition to the memory cell, to selectively write, erase, and read a specific memory cell in the array. Standard diodes (p-n type or Schottky-type diodes) are proposed as one of the solutions for the problem. However, the complexity of the fabrication of these diodes thwarts the implementation of diodes in a high density memory array.

### BRIEF SUMMARY

The present disclosure relates to memory arrays having phase-change memory cells with a resistive switch. The resistive switch can be a second phase-change cell, a programmable metallization cell, or other resistive cell configured for a high resistance level and a low resistance level. Methods of writing and reading to the memory cells are also described.

In one particular embodiment, this disclosure provides a memory cell comprising a phase-change memory cell stacked in series with a resistive switch. The resistive switch has a material that is switchable between a high resistance state and a low resistance state by the application of voltage.

In another particular embodiment, this disclosure provides a method for isolating a memory cell in a memory array, the memory array comprising a plurality of memory cells, with each memory cell comprising a phase-change memory cell stacked in series with a resistive switch changeable between a high resistance state and a low resistance state. The method comprises selecting a memory cell to be isolated, opening the switch for an unselected memory cell by resetting the resistance of the unselected memory cell in its high resistance state, and closing the switch for the selected memory cell by setting the resistance of the selected memory cell in its low resistance state. In some embodiments, the switch for every unselected memory cell is opened.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a schematic diagram of a memory array;

FIG. 2 is schematic side view of a phase-change memory cell;

FIG. 3 is a graphical illustration of time versus current for amorphous and crystalline phases for a phase-change memory cell;

FIG. 4 is a first embodiment of a phase-change memory cell with a resistive switch;

FIG. 5 is a graphical representation of an I-V curve for a programmable metallization cell;

FIGS. 6A-6H illustrate processes for reading and writing to the phase-change memory cell of FIG. 4;

FIG. 7 is a second embodiment of a phase-change memory cell with a resistive switch;

FIG. 8 is a graphical illustration of time versus current for amorphous and crystalline phases for a phase-change memory cell and a phase-change switch;

FIGS. 9A-9L illustrate processes for reading and writing to the phase-change memory cell of FIG. 7;

FIG. 10 is a third embodiment of a phase-change memory cell with a resistive switch;

FIG. 11 is a graphical representation of an I-V curve for a resistive switch;

FIG. 12 is a second graphical representation of an I-V curve for a resistive switch; and

FIGS. 13A-13L illustrate processes for reading and writing to the phase-change memory cell of FIG. 10.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

This disclosure is directed to memory cells and arrays that have phase-change memory cells stacked in series with a resistive switch, such as a programmable metallization cell, a second phase-change cell, or other resistive cell configured for changing between a high resistance level and a low resistance level. The switch may be a uni-polar or bi-polar switch. The construction of the stacked memory cells allows their isolation from other memory cells in a memory array, inhibiting sneaky currents.

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. Any definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

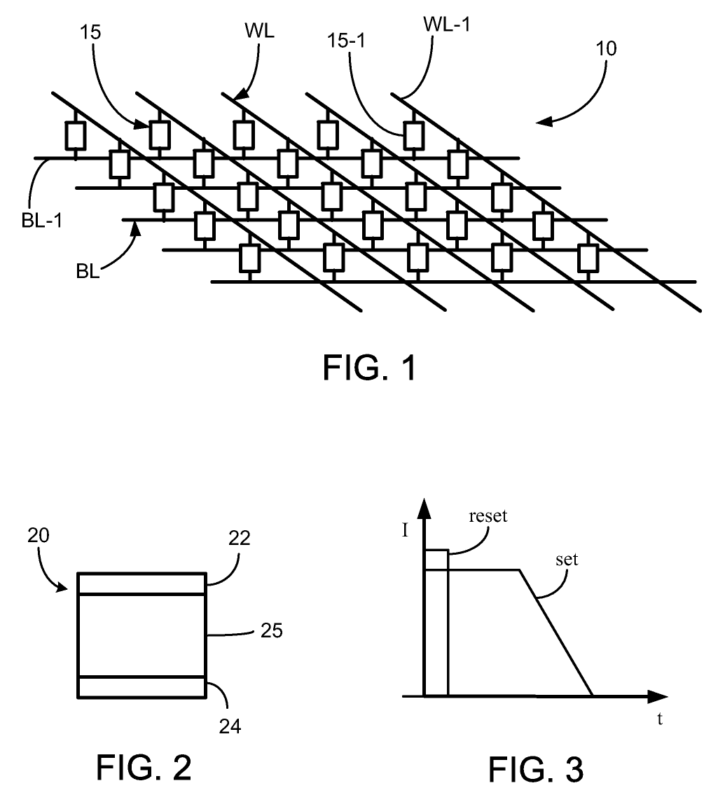

FIG. 1 shows a schematic of the memory array consisting of memory storage cells stacked with selective elements. Memory array 10 has a plurality of word lines WL and a plurality of bit lines BL. At the intersection of each of the word lines WL and bit lines BL is a memory storage cell 15. To access (i.e., read, write or erase) a specific memory cell 15, the corresponding bit line BL and word line WL are activated; for example, to access memory cell 15-1, bit line BL-1 and word line WL-1 are activated. To avoid loss of voltage or current from the selected memory cell 15 via the selected bit line BL and selected word line WL (known as “sneaky” voltage or current), non-selected memory cells 15 are inactivated, inhibiting passage of current or voltage there across. To inactivate non-selected memory cells 15, these cells 15 include a selecting element or switch that is set to an “open” configuration, inhibiting and sometimes not allowing sneaky current or voltage to pass through the switch and thus these cells 15. In some embodiments, in the open configuration, the resistance of the switch is high.

In accordance with this disclosure, each of the memory cells 15 has a phase-change memory cell stacked in series with a resistive selecting element or switch, such as a programmable metallization cell, a second phase-change cell, or other resistive cell configured for a high resistance level and a low resistance level. FIG. 2 illustrates a phase-change memory cell.

Phase change (PC) memory cell 20 of FIG. 2 has a first electrode 22, a second electrode 24 and a phase change material 25 therebetween. Phase change material 25 changes phases between stable crystalline and amorphous states. When in the crystalline phase, PC memory cell 20 has a low resistance, whereas when in the amorphous phase, PC memory cell 20 has a high resistance. In some embodiments, the low resistance state represents a “1” data bit and the high resistance state represents a “0” data bit.

Electrodes 22, 24 are electrically conducting and typically composed of at least one electrically conducting metal, metal oxide or metal nitride. In most embodiments, electrode 22 is the same as electrode 24, however, in alternate embodiments, electrode 22 is different than electrode 24. Suitable materials for electrodes 22, 24 include, but are not limited to, copper, silver, gold tungsten, titanium, aluminum, nickel, chromium, oxides thereof, nitrides thereof, and combinations and alloys thereof.

Suitable phase change materials 25 for cell 20 include, but are not limited to, binary and ternary compounds of Ge, Sb and Te, and any other materials that possess hysteretic phase change characteristics. The compounds involving Ge, Sb and Te are often referred to as GST compounds or GST materials. A specific example of a suitable material 25 is Ge₂Sb₂Te₅. In some embodiments, phase change material 25 is a chalcogenide material. In its standard phase, a chalcogenide material is in its amorphous state. Upon the application of heat, for example by passing a current therethrough, the chalcogenide material transitions to its crystalline state. The chalcogenide material can be reverted back to its amorphous state by melting, e.g., by the application of a higher heat.

In some embodiments, the change between crystalline and amorphous states of material 25 occurs at temperatures of about 200° C. or greater. At ambient temperature (e.g., below 150° C.) both phases are stable. Above the nucleation temperature (Tₙ) of phase-change material 25 (e.g., about 220° C.), fast nucleation of crystallites occurs. If the material is kept at an appropriate temperature for a sufficient length of time, the material becomes crystalline. To bring material 25 back to its amorphous state, it is necessary to raise the temperature above the melting temperature (Tₘ) (e.g., about 600° C.) and then cool it off rapidly. It is possible to reach both critical temperatures, nucleation temperature (Tₙ) and melting temperature (Tₘ), by causing a current to flow through material 25. In some embodiments, it is also possible to heat beyond the melting temperature and then either quench phase change material 25 quickly or cool it slowly over a longer period of time to attain the crystalline or amorphous state, respectively.

FIG. 3 illustrates a generic time versus current graph for amorphous and crystalline forms of phase change material 25. A short pulse of current through material 25 quickly heats material 20 to above its melting temperature and it quickly cools. As used herein, “reset” means that phase change material 25 is in its high resistance state, or is amorphous. A longer pulse of current through material 25 heats material 25 to above its nucleation temperature. A slow and gradual drop of the current cools and crystallizes phase change material 25. “Set” means that phase change material 25 is in its low resistance state, or is crystalline. In some embodiments, the amplitude of the current may be the same for “reset” and “set”, or in other embodiments, the current amplitude may be higher for “reset”.

As indicated above, each phase-change memory cell 20 is arranged in series with a resistive selecting element or switch, such as a programmable metallization cell, a second phase-change cell, or other resistive cell configured for a high resistance level and a low resistance level. The resistive selecting element or switch can be switched between a high resistance or “open” state, where passage of current or voltage is inhibited, and a low resistance or “closed” state, across which passage of current or voltage readily occurs. Thus, when incorporated into a memory array such as array 10 of FIG. 1, unselected memory cells 15 would be in an “open” state when reading, writing, or erasing a selected memory cell (e.g., memory cell 15-1).

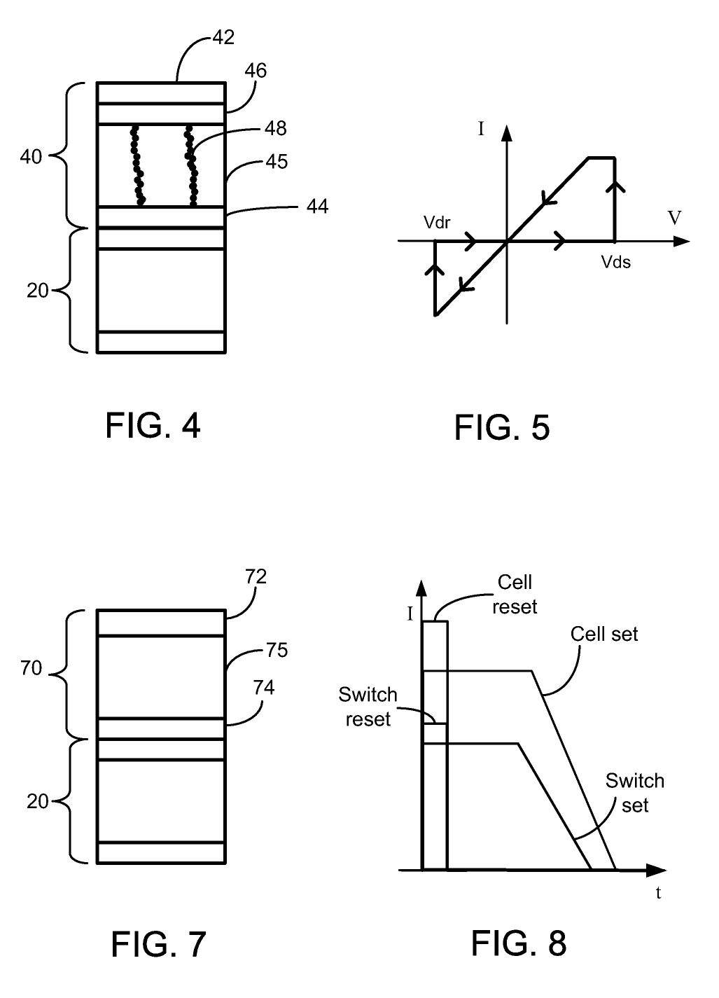

In some embodiments, the selecting element or switch is a programmable metallization cell, also referred to as a PMC or PM cell. Programmable metallization cell (PMC) memory is based on the physical re-location of superionic regions within an ion conductor solid electrolyte material. FIG. 4 illustrates phase-change cell 20 stacked with a PMC switch 40. In the illustrated embodiment, PMC switch 40 is above or on top of phase-change cell 20, although in other embodiments, phase-change cell 20 is above or on top of PMC switch 40. In some embodiments, a spacer layer or barrier layer may be positioned between phase-change cell 20 and PMC switch 40. PMC switch 40 has a first metal contact 42, a second metal contact 44 and an ion conductor solid electrolyte material 45 therebetween.

First metal contact 42 and second metal contact 44 can be formed of any useful metallic material. In many embodiments, one or both of first metal contact 42 and second metal contact 44 are formed of electrically conductive yet electrochemically inert metals such as, for example, platinum, gold, and the like. In some embodiments first metal contact 42 and/or second metal contact 44 have two or more metal layers, where the metal layer closest to ion conductor solid electrolyte material 45 is electrochemically inert while additional layers can be electrochemically active. In the embodiment of FIG. 4, PMC switch 40 includes a doping layer 46 between first metal contact 42 and ion conductor solid electrolyte material 45.

Ion conductor solid electrolyte material 45 can be formed of any useful material that provides for the formation of conducting filaments 48 or superionic clusters within ion conductor solid electrolyte material 45 that extend between metal contacts 42, 44 upon application of an electric field or current. In some embodiments, ion conductor solid electrolyte material 45 is a chalcogenide-type material such as, for example, GeS₂, GeSe₂, CuS₂, and the like. In other embodiments, ion conductor solid electrolyte material 45 is an oxide-type material such as, for example, NiO, WO₃, SiO₂, and the like.

In FIG. 4, PMC switch 40 is illustrated with conducting filaments 48 or superionic clusters within ion conductor solid electrolyte material 45. Filaments 48 are formed by the application of an electric field that allows cations from metal contact 44 to migrate toward metal contact 42, thus forming conducting filaments 48. The presence of conducting filaments 48 or superionic clusters within ion conductor solid electrolyte material 45 reduces electrical resistance and gives rise to the low resistance or “closed” state of PMC switch 40. If there are no conducting filaments 48 present, the resistance is higher, which is the “open” state. PMC switch 40 is a bi-polar switch, in that voltage or current of opposite polarities is needed to switch PMC switch 40 between its two states.

A general I-V curve for PMC switch 40 of FIG. 4 is illustrated in FIG. 5. An applied voltage of less than (more negative than) Vdr will provide an open cell (i.e., no or nearly no current flows through). As the voltage is increased through 0 V in a positive direction to Vds, switch 40 remains open. At Vds, filaments 48 electrically connect contacts 42, 44 allowing current to flow through PMC switch 40. As the voltage is reversed, filament 48 remains and switch 40 remains closed. As the voltage is decreased to negative from Vds to Vdr, the voltage reverses its polarity so that filament 48 depletes at Vdr, where no filament 48 is present. At this point (Vdr), the resistance increases again, allowing little or no current through switch 40. This cycle repeats.

As an example, to close PMC switch 40, a voltage higher than Vds is applied, with a compliant current (e.g., of about 50 μA, to prevent growing too thick of filament 48). PMC switch 40, in the low resistance state, can be read with a low current flow. To open PMC switch 40, a voltage lower than Vdr (e.g., of about −0.7 V with Vdr=−0.5V) is applied, to change PMC switch 40 to the high resistance state. PMC switch 40 can be read with a low current flow. In some embodiments, a compliant current is not needed to open PMC switch 40.

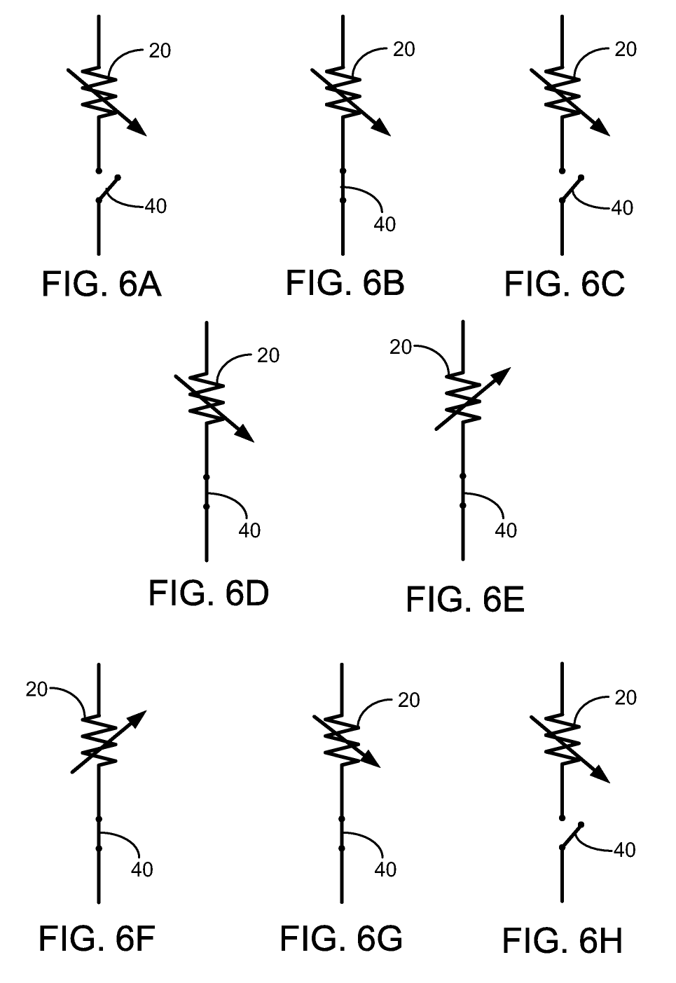

FIGS. 6A-6H illustrate reading and writing to a storage cell that has phase-change memory cell 20 with PMC switch 40.

In FIG. 6A, PC cell 20 is in the low resistance (i.e., crystalline) state and PMC switch 40 is open, in its high resistance state with no filament present. In FIG. 6B, most of the bias voltage is across PMC switch 40, because PC cell 20 is in its low resistance state. Thus, a sufficient voltage is applied to form a filament and close PMC switch 40. This current, however, is not sufficient to switch the state of PC cell 20. At this point, with PMC switch 40 closed, PC cell 20 can read; the resistance state is low, which correlates to, for example, the “1” data state. In FIG. 6C, PMC switch 40 is opened, by applying a negative voltage to destroy the filament and recreate the high resistance state.

To write to PC cell 20, PMC switch 40 is first closed in FIG. 6D by the application of sufficient voltage to form a filament and place PMC switch 40 in the low resistance, closed state. This current is not sufficient to switch the state of PC cell 20. To switch the data state of PC cell 20 to the high resistance state, a high current pulse is applied to PC cell 20 (see “reset” in FIG. 3), to melt the phase-change material and quickly cool it to its amorphous state. At this point in FIG. 6E, PC cell 20 is in the high resistance state, which correlates to, for example, the “0” data state. The high resistance state of PC cell 20 will inhibit passage of any sneaky current, so switch 40 may be opened or may be left closed.

To read this data state of PC cell 20, in FIG. 6F, switch 40 is first closed if needed. PC cell 20 is read to be in the high resistance state, which correlates to, for example, the “0” data state.

To switch the data state of PC cell 20 to the low resistance state, current is applied to PC cell 20 and slowly decreased (see “set” in FIG. 3), to raise the phase-change material above its nucleation temperature and then allow crystals to form. As illustrated in FIG. 6G, PMC switch 40 remains closed. In FIG. 6H, PMC switch 40 is opened, by applying a negative voltage to destroy the filament and recreate the high resistance state, so that no sneaky current is able to pass through PC cell 20 in the low resistance state.

In other embodiments, the selecting element or switch is a phase-change cell. In these embodiments, both the memory cell and the switch are phase-change cells; the two phase-change cells may be the same or may be different.

FIG. 7 illustrates phase-change (PC) cell 20 stacked with a phase-change (PC) switch 70. In the illustrated embodiment, PC switch 70 is above or on top of phase-change cell 20, although in other embodiments, phase-change cell 20 is above or on top of PC switch 70. Similar to phase-change cell 20, PC switch 70 has a first electrode 72, a second electrode 74 and a phase change material 75 therebetween. Phase change material 75 changes phases between stable crystalline and amorphous states. When in the crystalline phase, PC switch 70 has a low resistance and is “closed”, whereas when in the amorphous phase, PC switch 70 has a high resistance and is “open”. PC switch 70 is a uni-polar switch, in that voltage or current of a single polarity will switch PC switch 70 between its two states.

Because PC cell 20 and PC switch 70 both function under the same principle of the resistivity based on material structural change, PC cell 20 and PC switch 70 must be sufficiently different so that PC cell 20 does not switch states when PC switch 70 is opened or closed. See FIG. 8, where it is shown that the reset current for PC cell 20 is greater than the reset current for PC switch 70. Similarly, the set current for PC cell 20 is greater than the set current for PC switch 70. The amplitude of the set current for cell 20 may be greater than or less than the reset current for switch 70.

In most embodiments, the physical structure or material properties differ between PC cell 20 and PC switch 70. In a first example, phase-change material 25 for PC cell 20 has a nucleation temperature and/or a melting temperature greater than that of phase-change material 75 for PC switch 70. In this structure, PC cell 20 and PC switch 70 may have identical or different shapes. In a second example, electrodes 22, 24 of PC cell 20 have a different area than electrodes 72, 74 of PC switch 70. Electrodes 72, 74 are configured to produce the crystalline-amorphous change in phase-change material 75 of switch 70 before the phase change occurs in phase-change material 25 of cell 20. Alternately, electrodes 22, 24 of PC cell 20 have different thermal properties than electrodes 72, 74 of PC switch 70. Electrodes 72, 74 are configured to produce the crystalline-amorphous change in phase-change material 75 of switch 70 before the phase change occurs in phase-change material 25 of cell 20.

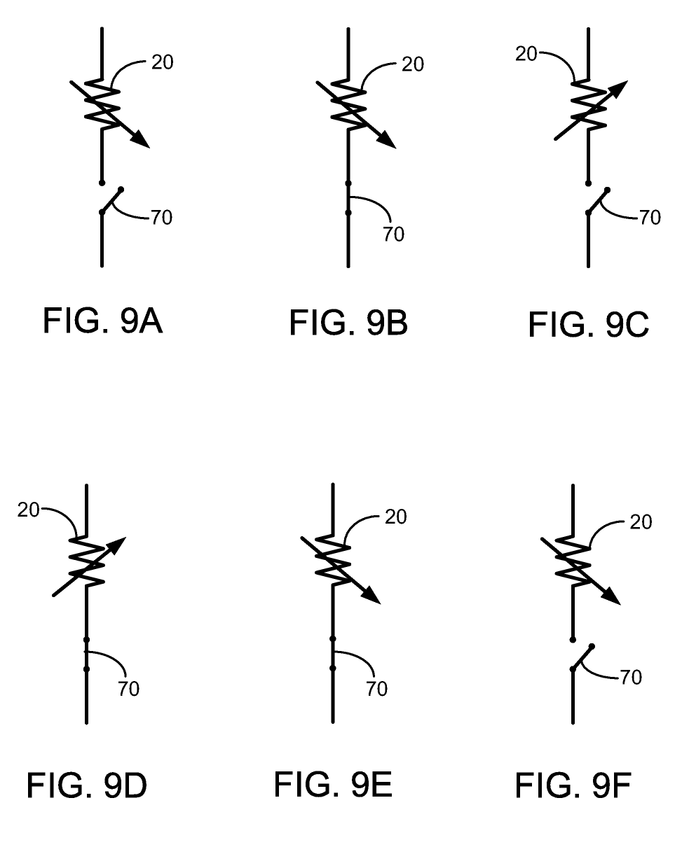

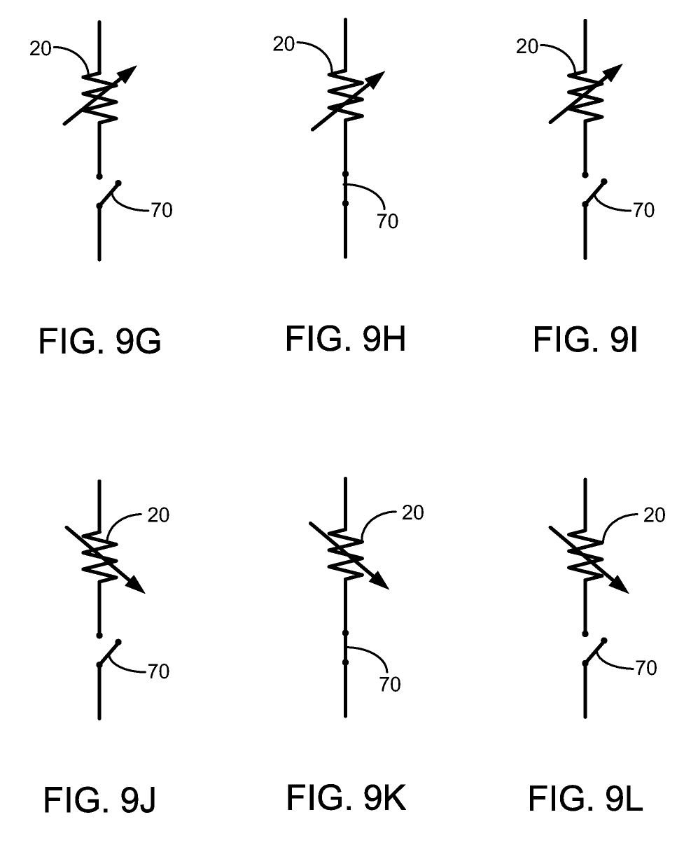

FIGS. 9A-9L illustrate reading and writing to a storage cell that has phase-change memory cell 20 with PC switch 70.

In FIG. 9A, PC cell 20 begins in the low resistance (i.e., crystalline) state and PC switch 70 is open, amorphous in its high resistance state. In FIG. 9B, a longer current pulse (“switch set” in FIG. 8) is applied to change PC switch 70 to its low resistance state and close PC switch 70. This current pulse, however, is not sufficient to switch the state of PC cell 20. At this point, with PC switch 70 closed, PC cell 20 can be read; the resistance state is low, which correlates to, for example, the “1” data state.

To write the high resistance state (for example, “0” data state) to PC cell 20, a high current pulse is applied to PC cell 20 (“cell reset” in FIG. 8), to melt the phase-change material and quickly cool it to its amorphous state. At this point in FIG. 9C, PC cell 20 is in the high resistance state, which correlates to, for example, the “0” data state. The current pulse also melts the phase-change material of switch 70, opening the switch in its high resistance state.

To write the low resistance state (for example, “1” data state) to PC cell 20, switch 70 is first closed in FIG. 9D by switching PC switch 70 to its crystalline state (“switch set” in FIG. 8). Subsequently or simultaneously, PC cell 20 is switched to its low resistance, crystalline state, in FIG. 9E by the appropriate current (“cell set” in FIG. 8). Switch 70 is then “reset” in FIG. 9F to its high resistance, amorphous state, so that no sneaky current is able to pass through PC cell 20 in the low resistance state.

To read this data state of PC cell 20, in FIG. 9G, switch 70 is closed in FIG. 9H by the appropriate current (“switch set” in FIG. 8). PC cell 20 is read to be in the high resistance state, which correlates to, for example, the “0” data state. After reading, PC switch 70 is opened (“switch reset” in FIG. 8) in FIG. 9I.

Similarly, to read the opposite data state of PC cell 20, in FIG. 9J, switch 70 is closed in FIG. 9K by the appropriate current (“switch set” in FIG. 8). PC cell 20 is read to be in the low resistance state, which correlates to, for example, the “1” data state. After reading, PC switch 70 is opened (“switch reset” in FIG. 8) in FIG. 9L, so that no sneaky current is able to pass through PC cell 20 in the low resistance state.

In yet other embodiments, the selecting element or switch is a ReRAM cell. In these embodiments, the ReRAM switch includes a material that changes resistance by the application of a current or voltage across the switch.

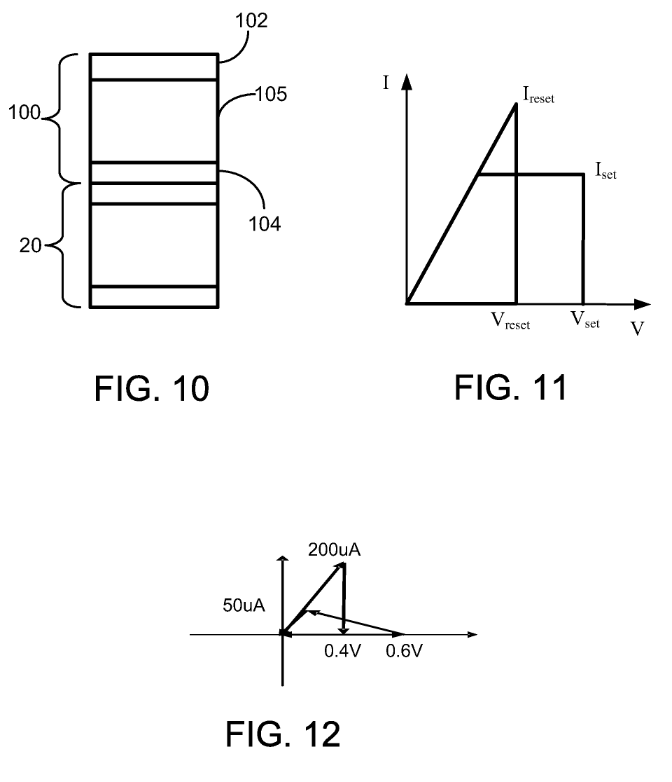

FIG. 10 illustrates phase-change cell 20 stacked with a resistive RAM (ReRAM) switch 100. In the illustrated embodiment, ReRAM switch 100 is above or on top of phase-change cell 20, although in other embodiments, phase-change cell 20 is above or on top of ReRAM switch 100. ReRAM switch 100 has a first contact 102, a second contact 104 and a metal oxide material 105 therebetween. Similar to an ion conductor solid electrolyte material 45 of PMC switch 40 of FIG. 4, metal oxide material 105 changes resistance between a high resistance state (e.g., about 10⁶ ohms) (“open”) and a low resistance state (e.g., about 10³ ohms) (“closed”). ReRAM switch 100 is a uni-polar switch, in that voltage or current of a single polarity will switch ReRAM switch 100 between its two states.

Examples of suitable materials for contacts 102, 104 include Pt, Ta, W, Au, Ir, Ru, and Ti. Metal oxide material 105 can be formed of any useful material that changes resistance by the application of current or voltage thereto; in some embodiments, heating of metal oxide material 105 by current changes its resistance. Suitable resistive switching materials for material 105 include a wide variety of transition metal oxides or complex oxides. Examples of metal oxide material 105 include (but are not limited to) NiOₓ, TiO₂, ZrO₂, Cu₂O, Nb₂O₃, WO₃, and In₂O₃ and alloys or mixtures such as Nb:SrZrO₃, SrTiO₃, Pr_{0.7}Ca_{0.3}MnO₃, and Cr:SrTiO₃.

FIG. 11 illustrates a generic current versus voltage (I-V) graph for programming (set) and erasing (reset) metal oxide material 105 of ReRAM switch 100. “Reset” means that metal oxide material 105 is altered from its low resistance state to its high resistance state. “Set” means that metal oxide material 105 is altered from its high resistance state to its low resistance state. In some specific embodiments, Iₛₑₜ is about 100 μA and Iᵣₑₛₑₜ is about 80 μA, Vₛₑₜ is about 0.6 V and Vᵣₑₛₑₜ is about 0.4 V. The individual I-V characteristics of ReRAM switch 110 are shown in FIG. 12.

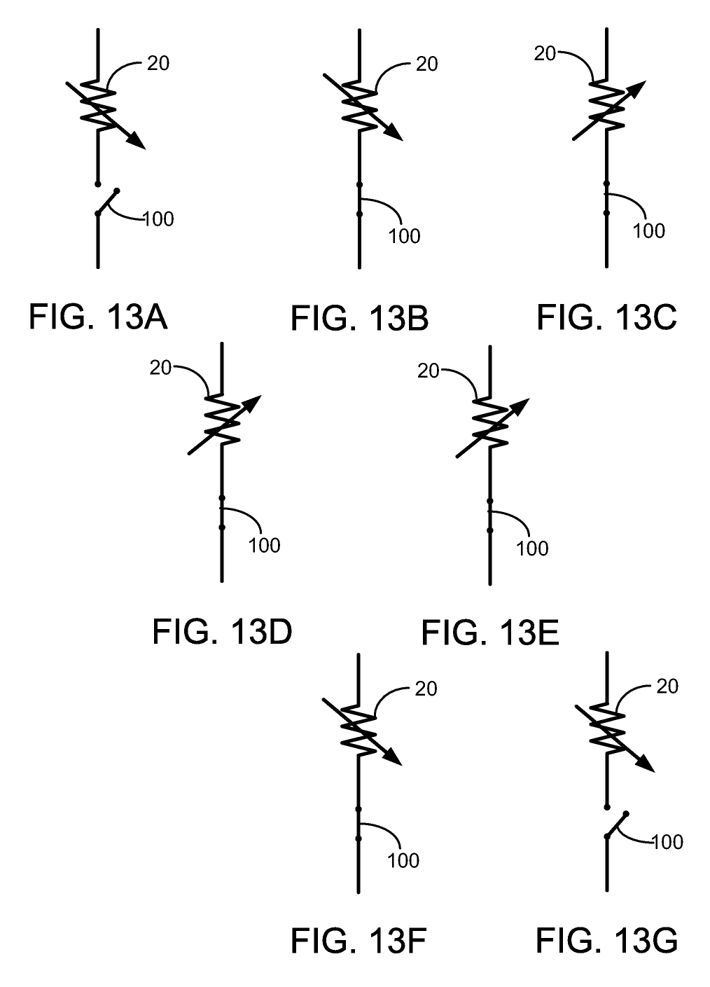

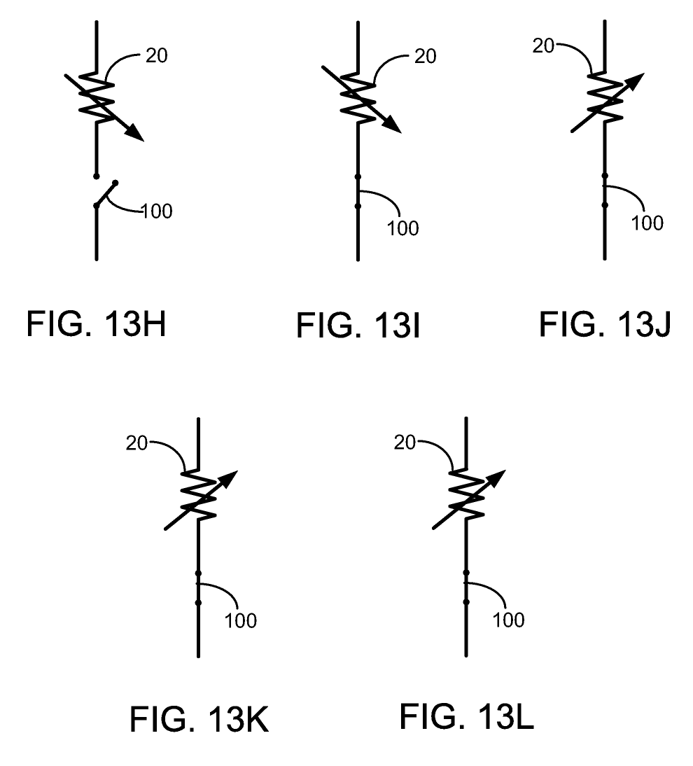

In one specific embodiment, PC cell 20 has a high resistance state of 2×10⁶ ohms and a low resistance state of 2×10³ ohms, while ReRAM switch 100 has a high resistance state of 1×10⁶ ohms and a low resistance state of 2×10³ ohms. The write, erase, and read functions are shown in FIGS. 13A-13L.

FIGS. 13A-13C illustrate erasing data from memory cell 20. In FIG. 13A, PC cell 20 begins in the low resistance (i.e., crystalline) state and ReRAM switch 100 is open, in its high resistance state. In some embodiments, at this point, PC cell 20 has a resistance of 2 kΩ and switch 100 has a resistance of 1 MΩ. In FIG. 13B, voltage (“set” in FIG. 12) is applied to change ReRAM switch 100 to its low resistance state and close ReRAM switch 100; the current across the combination is 50 μA. This current pulse, however, is not sufficient to switch the state of PC cell 20. At this point, with ReRAM switch 100 closed, PC cell 20 can read; the resistance state is low, which correlates to, for example, the “1” data state. In some embodiments, at this point, PC cell 20 has a resistance of 4 kΩ and switch 100 has a resistance of 2 kΩ. With ReRAM switch 100 closed, PC cell 20 can be switched to its high resistance, amorphous state (“reset” in FIG. 3); the current across the combination is 100 μA, which is not sufficient to switch the state of ReRAM switch. In some embodiments, at this point, PC cell 20 has a resistance of 2 MΩ and switch 100 has a resistance of 2 kΩ.

FIGS. 13D-13G illustrate writing to memory cell 20. In FIG. 13D, PC cell 20 is in its high resistance state and switch 100 is closed. In some embodiments, at this point, PC cell 20 has a resistance of 2 MΩ and switch 100 has a resistance of 2 kΩ. To confirm switch 100 is closed, voltage (“set” of FIG. 12) is applied to switch 100; this voltage does not affect PC cell 20. At this point in FIG. 13E, PC cell 20 is in the high resistance state, which correlates to, for example, the “0” data state. In some embodiments, at this point, PC cell 20 still has a resistance of 2 MΩ and switch 100 still has a resistance of 2 kΩ, but the current across the combination is 80 μA.

To write the low resistance state (for example, “1” data state) to PC cell 20, switch 100 is confirmed closed in FIG. 13F. Subsequently or simultaneously, PC cell 20 is switched to its low resistance, crystalline state, in FIG. 13F by the appropriate current (“set” in FIG. 3). In some embodiments, at this point, PC cell 20 has a resistance of 4 kΩ and switch 100 still has a resistance of 2 kΩ, but the current across the combination is 200 μA. Switch 100 is then “reset” in FIG. 13G to its high resistance state (“reset” in FIG. 12), so that no sneaky current is able to pass through PC cell 20 in the low resistance state.

FIGS. 13H-13L illustrate reading memory cell 20, with FIGS. 13H-13J reading the low data state (e.g., “1”) and FIGS. 13K-13L reading the high data state (e.g., “0”).

To read this data state of PC cell 20 of FIG. 13H (in some embodiments, at this point, PC cell 20 has a resistance of 4 kΩ and switch 100 has a resistance of 1 ME), switch 100 is closed by the application of “set” voltage (of FIG. 12). In some embodiments, at this point, PC cell 20 still has a resistance of 4 kΩ but switch 100 has a resistance of 2 kΩ. PC cell 20 is read to be in the low resistance state, which correlates to, for example, the “1” data state. After reading, ReRAM switch 100 is opened (“reset” in FIG. 12) in FIG. 13J so that no sneaky current is able to pass through PC cell 20 in the low resistance state. In some embodiments, at this point, PC cell 20 still has a resistance of 4 kΩ but open switch 100 has a resistance of 1 MΩ.

To read the opposite data state of PC cell 20 (in some embodiments, at this point, PC cell 20 has a resistance of 2 MΩ and switch 100 has a resistance of 2 kΩ). ReRAM switch 100 is confirmed closed by the appropriate current (“set” in FIG. 12); this voltage does not affect PC cell 20. In FIG. 13L, PC cell 20 is read to be in the high resistance state, which correlates to, for example, the “0” data state. The resistance across PC cell 20 and ReRAM switch 100 remains the same, in some embodiments, 2 MΩ and 2 kΩ, respectively.

In each of the embodiments described above, although an unselected switch 40, 70, 100 may be “open”, in the high resistance state, some sneaky current may cross unselected switch 40, 70, 100 and PC cell 20. This amount of current, however, is insignificant compared to the current passing through the selected PC cell 20, and this sneaky current will not deleteriously affect the reading or writing of the selected PC cell.

The structures of this disclosure, including any or all of the memory cells and switches may be made by thin film techniques such as chemical vapor deposition (CVD), physical vapor deposition (PVD), atomic layer deposition (ALD), sputtering, and molecular beam epitaxy (MBE).

Thus, embodiments of the PHASE CHANGE MEMORY CELL WITH SELECTING ELEMENT are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A memory cell comprising a phase-change memory cell stacked in series with a resistive switch, the resistive switch comprising a material switchable between a high resistance state and a low resistance state by the application of a voltage.

2. The memory cell of claim 1 wherein the resistive switch is a bi-polar resistive switch.

3. The memory cell of claim 2 wherein the resistive switch is a programmable metallization switch.

4. The memory cell of claim 3 wherein the programmable metallization switch comprises a first contact, a second contact, and an ion conductor solid electrolyte material between the contacts.

5. The memory cell of claim 1 wherein the resistive switch is a uni-polar resistive switch.

6. The memory cell of claim 5 wherein the resistive switch is a phase-change switch.

7. The memory cell of claim 6 wherein the phase-change switch comprises a first electrode, a second electrode, and a chalcogenide material between the electrodes.

8. The memory cell of claim 5 wherein the resistive switch is a ReRAM switch.

9. The memory cell of claim 8 wherein the ReRAM switch comprises a first contact, a second contact, and metal oxide material between the contacts.

10. A memory array comprising a plurality of word lines and a plurality of bit lines, with a memory cell present at each intersection of a word line and a bit line, each memory cell comprising a phase-change memory cell stacked in series with a resistive switch, the resistive switch comprising a material switchable between a high resistance state and a low resistance state, wherein in the high resistance state the switch is open and in the low resistance state the switch is closed.

11. The memory array of claim 10 wherein the resistive switch is a programmable metallization switch.

12. The memory array of claim 10 wherein the resistive switch is a phase-change switch.

13. The memory array of claim 10 wherein the resistive switch is a ReRAM switch.

14. A method of isolating a memory cell in a memory array, the memory array comprising a plurality of memory cells, with each memory cell comprising a phase-change memory cell stacked in series with a resistive switch changeable between a high resistance state and a low resistance state, the method comprising:
selecting a memory cell to be isolated;
opening the switch for an unselected memory cell by resetting the resistance of the unselected memory cell in its high resistance state; and
closing the switch for the selected memory cell by setting the resistance of the selected memory cell in its low resistance state.

15. The method of claim 14 further comprising opening the switch for every unselected memory cell by resetting the resistance of the unselected memory cells in their high resistance state.

16. The method of claim 14 wherein opening the switch for an unselected memory cell comprises applying a voltage to remove any conducting filaments present in an ion conductor solid electrolyte material.

17. The method of claim 14 wherein opening the switch for an unselected memory cell comprises applying a voltage pulse to create an amorphous state in a phase-change material.

18. The method of claim 14 wherein opening the switch for an unselected memory cell comprises applying a voltage to place a metal oxide material in its high resistance state.
